(19) United States
(12) Patent Application Publication
(10) Pub. No.: US 2009/0123004 A1
(43) Pub. Date: May 14, 2009

(54) Method and system for automated volume adjustments for a marketing system

(76) Inventors: Jonathan Otto, Palm Beach, FL (US); Raymond J. Mueller, Palm Beach Gardens, FL (US); Andrew Van Luchene, Santa Fe, NM (US)

Correspondence Address: SIMPSON & SIMPSON, PLLC, 5555 MAIN STREET, WILLIAMSVILLE, NY, 14221-5406, US

(21) Appl. No.: 11/985,181

(22) Filed: Nov. 14, 2007

(51) Int. Cl. H03G 3/00

(52) U.S. Cl. 381/104

(57) ABSTRACT

A method for adjusting volume for a marketing system, including the steps of: determining, using a processor in a general-purpose computer, a parameter associated with the marketing system; generating, using the processor, a volume control level based on the parameter; and controlling, using the processor and an interface element for the computer, an audio output portion of a sales offer from an audio component of the marketing system such that the audio output portion matches the volume control level. The general-purpose computer is arranged to perform the steps of determining, generating, and controlling. In a preferred embodiment, the parameter is an ambient noise level proximate the marketing system and determining a parameter includes measuring the ambient noise level proximate the marketing system. In a first embodiment, the parameter is a temporal parameter. A system for adjusting volume for a selling system.

### CROSS-REFERENCE TO RELATED APPLICATIONS

This application is related to: U.S. patent application Ser. No. 09/052,093 entitled “Vending Machine Evaluation Network” and filed Mar. 31, 1998; U.S. patent application Ser. No. 09/083,483 entitled “Method and Apparatus for Selling an Aging Food Product” and filed May 22, 1998; U.S. patent application Ser. No. 09/282,747 entitled “Method and Apparatus for Providing Cross-Benefits Based on a Customer Activity” and filed Mar. 31, 1999; U.S. patent application Ser. No. 08/943,483 entitled “System and Method for Facilitating Acceptance of Conditional Purchase Offers (CPOs)” and filed on Oct. 3, 1997, which is a continuation-in-part of U.S. patent application Ser. No. 08/923,683 entitled “Conditional Purchase Offer (CPO) Management System For Packages” and filed Sep. 4, 1997, which is a continuation-in-part of U.S. patent application Ser. No. 08/889,319 entitled “Conditional Purchase Offer Management System” and filed Jul. 8, 1997, which is a continuation-in-part of U.S. patent application Ser. No. 08/707,660 entitled “Method and Apparatus for a Cryptographically Assisted Commercial Network System Designed to Facilitate Buyer-Driven Conditional Purchase Offers,” filed on Sep. 4, 1996 and issued as U.S. Pat. No. 5,794,207 on Aug. 11, 1998; U.S. patent application Ser. No. 08/920,116 entitled “Method and System for Processing Supplementary Product Sales at a Point-Of-Sale Terminal” and filed Aug. 26, 1997, which is a continuation-in-part of U.S. patent application Ser. No. 08/822,709 entitled “System and Method for Performing Lottery Ticket Transactions Utilizing Point-Of-Sale Terminals” and filed Mar. 21, 1997; U.S. patent application Ser. No. 09/135,179 entitled “Method and Apparatus for Determining Whether a Verbal Message Was Spoken During a Transaction at a Point-Of-Sale Terminal” and filed Aug. 17, 1998; U.S. patent application Ser. No. 09/538,751 entitled “Dynamic Propagation of Promotional Information in a Network of Point-of-Sale Terminals” and filed Mar. 30, 2000; U.S. patent application Ser. No. 09/442,754 entitled “Method and System for Processing Supplementary Product Sales at a Point-of-Sale Terminal” and filed Nov. 12, 1999; U.S. patent application Ser. No. 09/045,386 entitled “Method and Apparatus For Controlling the Performance of a Supplementary Process at a Point-of-Sale Terminal” and filed Mar. 20, 1998; U.S. patent application Ser. No. 09/045,347 entitled “Method and Apparatus for Providing a Supplementary Product Sale at a Point-of-Sale Terminal” and filed Mar. 20, 1998; U.S. patent application Ser. No. 09/083,689 entitled “Method and System for Selling Supplementary Products at a Point-of Sale and filed May 21, 1998; U.S. patent application Ser. No. 09/045,518 entitled “Method and Apparatus for Processing a Supplementary Product Sale at a Point-of-Sale Terminal” and filed Mar. 20, 1998; U.S. patent application Ser. No. 09/076,409 entitled “Method and Apparatus for Generating a Coupon” and filed May 12, 1998; U.S. patent application Ser. No. 09/045,084 entitled “Method and Apparatus for Controlling Offers that are Provided at a Point-of-Sale Terminal” and filed Mar. 20, 1998; U.S. patent application Ser. No. 09/098,240 entitled “System and Method for Applying and Tracking a Conditional Value Coupon for a Retail Establishment” and filed Jun. 16, 1998; U.S. patent application Ser. No. 09/157,837 entitled “Method and Apparatus for Selling an Aging Food Product as a Substitute for an Ordered Product” and filed Sep. 21, 1998, which is a continuation of U.S. patent application Ser. No. 09/083,483 entitled “Method and Apparatus for Selling an Aging Food Product” and filed May 22, 1998; U.S. patent application Ser. No. 09/603,677 entitled “Method and Apparatus for selecting a Supplemental Product to offer for Sale During a Transaction” and filed Jun. 26, 2000; U.S. Pat. No. 6,119,100 entitled “Method and Apparatus for Managing the Sale of Aging Products and filed Oct. 6, 1997 and U.S. Provisional Patent Application Ser. No. 60/239,610 entitled “Methods and Apparatus for Performing Upsells” and filed Oct. 11, 2000.

By “related to” we mean that the present application and the applications noted above are in the same general technological area and have a common inventor or assignee. However, “related to” does not necessarily mean that the present application and any or all of the applications noted above are patentably indistinct, or that the filing date for the present application is within two months of any of the respective filing dates for the applications noted above.

### FIELD OF THE INVENTION

The present invention relates generally to methods and systems for automatically controlling the audio portion of a marketing offer. In particular, the invention relates to methods and systems for controlling the volume of the audio portion with respect to predefined parameters such as ambient noise level.

### BACKGROUND OF THE INVENTION

Marketing offers typically include a visual portion, for example, displayed on a screen facing a consumer at a counter or at a kiosk, and an audio portion, for example, broadcast through speakers associated with the screen. The volume level for the audio portion is fixed and is changed by an intervention of some sort by personnel associated with the system presenting the offer. Unfortunately, the fixed volume level can be inappropriate in light of actual conditions in the setting in which the speakers are located. For example, in a retail establishment, at slow times, ambient noise levels are low and the fixed volume level can be too high, which can be irritating to potential customers. On the other hand during busy times at the retail location, ambient noise levels increase and the fixed volume level can be too low, making the audio portion difficult or impossible to understand. Further, the fixed volume level may be inappropriate for other reasons, such as customer preference and other operations at the retail location. Unfortunately, given the realities of operating a retail establishment, it is not practical to expect an employee or manager to adjust the volume control of the audio portion (manually or otherwise) based upon how busy the retail establishment is at any given time during the day or other considerations.

Thus, there is a long-felt need to provide a method and system for automatically adjusting volume levels for the audio portion of a marketing offer.

### SUMMARY OF THE INVENTION

The present invention broadly comprises a method for adjusting volume for a marketing system, including the steps of: determining, using a processor in a general-purpose computer, a parameter associated with the marketing system; generating, using the processor, a volume control level based on the parameter; and controlling, using the processor and an interface element for the computer, an audio output portion of a sales offer from an audio component of the marketing system such that the audio output portion matches the volume control level. The general-purpose computer is arranged to perform the steps of determining, generating, and controlling. In a preferred embodiment, the parameter is an ambient noise level proximate the marketing system and determining a parameter includes measuring the ambient noise level proximate the marketing system.

In a first embodiment, the parameter is a temporal parameter and determining a parameter includes determining a current temporal parameter. In another embodiment, the temporal parameter is a time of day or a day of week. In a second embodiment, the parameter is a volume of transactions during a specified time period in a retail location in which the sales system is located and determining a parameter includes determining the volume of transactions.

In another embodiment, the specified time period is a current time or a previous period of time. In a third embodiment, the marketing system is associated with a point of sale (POS) device, the parameter is the identity of personnel operating the POS device, and determining a parameter includes identifying the personnel.

In a fourth embodiment, the parameter is the identity of a customer engaged with the marketing system and determining a parameter includes identifying the customer. In another embodiment, identifying the customer includes retrieving a volume preference for the customer from a memory element for the computer and generating a volume control level includes using the volume preference as the volume control level.

In a fifth embodiment, the method includes the steps of transmitting a query to the marketing system, using the processor and the interface element, for presentation to the customer regarding a preferred volume level; and storing a response to the query, received from the marketing system via the interface element, using the interface element and the processor, in a memory element for the computer. The query includes a volume preference for the customer. The general-purpose computer is specially programmed to perform the steps of transmitting and storing and determining a volume level includes using the volume preference as the volume level. In a sixth embodiment, a parameter is the profitability associated with operation of the selling system and determining a parameter includes determining profitability associated with a volume control level. In a further embodiment, determining profitability includes using a set of rules and an artificial intelligence program to determine profitability.

The present invention also broadly comprises a system for adjusting volume for a marketing system.

It is a general object of the present invention to provide a system and method to control an audio output for a marketing system at an optimal level.

It is another object of the present invention to provide a system and method to automatically control an audio output for a marketing system based on predefined parameters.

These and other objects and advantages of the present invention will be readily appreciable from the following description of preferred embodiments of the invention and from the accompanying drawings and claims.

### BRIEF DESCRIPTION OF THE DRAWINGS

The nature and mode of operation of the present invention will now be more fully described in the following detailed description of the invention taken with the accompanying drawing figures, in which:

FIG. 1 is a schematic block diagram of a present invention system for adjusting volume for a kiosk in a marketing system;

FIG. 2 is a schematic block diagram of a present invention system for adjusting volume for a wireless communications device interfaced with a marketing system;

FIG. 3 is a flow chart of a present invention method for controlling an audio output for a marketing system.

### DETAILED DESCRIPTION OF THE PREFERRED EMBODIMENT

At the outset, it should be appreciated that like drawing numbers on different drawing views identify identical, or functionally similar, structural elements of the invention. While the present invention is described with respect to what is presently considered to be the preferred aspects, it is to be understood that the invention as claimed is not limited to the disclosed aspects.

Furthermore, it is understood that this invention is not limited to the particular methodology, materials and modifications described and as such may, of course, vary. It is also understood that the terminology used herein is for the purpose of describing particular aspects only, and is not intended to limit the scope of the present invention, which is limited only by the appended claims.

Unless defined otherwise, all technical and scientific terms used herein shall include the same meaning as commonly understood to one of ordinary skill in the art to which this invention belongs. Although any methods, devices or materials similar or equivalent to those described herein can be used in the practice or testing of the invention, the preferred methods, devices, and materials are now described.

The following non-limiting definitions are applicable to the present invention:

Business—includes any business enterprise formed for the purpose of providing a product or service, which may or may not be for profit.

Business objective—includes any desired outcome of a business or business owner, including, for example, acquisition of new customers, delivery of one or more marketing offers, increases or improvements in product quality or service, sales, profits, customer counts, customer visitation frequency, customer loyalty, average check, average item counts, order contents, speed of service measurements, labor rates, sales per labor hour, year over year or same store sales, percentage market share, annual or periodic growth rates, employee or management retention or turnover rate, inventory control or turns, inventory waste, raw or finished waste, increases in stock prices, improved return on assets or equity, or any other objective as determined by management or other authorized individual or as established by rules or other metrics including or stored in a system designed for such purposes.

Business Information—includes any information that is provided, known, gathered, assumed or is otherwise determined or stored that is related to or is about or otherwise helps understand, define, operate, improve, track or report the performance of, a business, for example, customer acquisition and sales data, marketing information, click-through rates, conversion rates, profit and loss information, accounting information, financial information, statistics and ratios, customer information, sponsor information, information about any one or more business, customer or sponsor objectives, or any other information, business metrics and data gathered or stored or otherwise possessed or accessible by a business and/or any of its affiliates, sponsors, customers or investors.

Controller—means any one or more of the following electronic devices including, but not limited to: cell phones, Personal Digital Assistants or (PDA's), Blackberry or similar devices, such as hand held computers, MP3 players, or any other personal electronic device that has one or more of a keyboard, speaker, microphone, one or more buttons, or any other similar devices that provides a User with Input and/or Output Functionality and Remote Connectivity. A Controller may be or include one or more of a Display and/or a Server or other computing devices or means of computing.

Coupon—includes an offer presented in the form of an electronic or printed ticket or document which may include a discount or rebate when purchasing one or more products from a business or sponsor. In certain embodiments, a coupon may include a bar code, RFID, or other means of identification, which may include information that can verify any one or more of the type of coupon, valid offer dates, customer, business or sponsor information, discount amounts, restrictions, permissions, items required to purchase to receive a discount or rebate, and/or items to which a discount or rebate applies, location information, including where the coupon is valid, e.g., which store or stores, or website, and/or any other information that might assist or be of benefit to the issuer or recipient or the processor, e.g., a cashier, and/or the processing system, e.g., a POS terminal or POS system, and/or a sponsor or other business entity, and/or any information that might encourage distribution, delivery, redemption or use of any such coupon or that might improve the results of any coupon or coupon marketing campaign, e.g., a viral marketing campaign or new product introduction.

Customer Facing Display—includes any device accessible by an end user or customer that includes at least one of a display, input means, e.g., a touch screen or keyboard, or other output means, e.g., a speaker. In certain embodiments, a Customer Facing Display may include a Kiosk, POS Terminal, or other computing device, such as a cell phone, PDA, laptop or PC. In certain embodiments a customer facing display may be a POS or POS terminal and vice versa.

Customer Identifier—includes, but is not limited to a cell phone, an RFID tag, a credit card, a debit card, a frequent shopper card or number, a coupon, a license plate, a check, a loyalty or gift card, fingerprint or other biometric input, a driver's license, or other identification means.

Customer Information—includes any information that is provided, known, gathered, assumed or is otherwise determined or stored that is related to or is about or otherwise helps understand or define a customer and/or a customer's buying habits, preferences or tendencies. Such information may include the customer's (or any related person, e.g., a child) order history, order contents, ideal order acceptance or rejection data, willingness to accept or reject one or more marketing offers or messages (either specific or types or categories of offers), price point or price elasticity, tendency to attempt to game other otherwise attempt to take advantage of the system or marketing program, average order total, e.g., average check, average item count, e.g., average number of items in a given order, average customer count, e.g., how many persons in the party on average, any demographic information, e.g., income, race, mailing address, zip codes, phone numbers, household total income, number of children, age, sex, number and type of internet enabled devices, participation in one or more marketing programs, willingness to use kiosks, cell phones or other ordering devices, prior ordering history, including willingness or tendency to accept pre, mid and/or post order marketing offers, e.g., suggestive selling, cross selling, sponsor rewards, or any other offers, and/or any other information gathered or provided by/from the customer, e.g., preferences information gathered by observing such customer behavior, e.g., does customer switch from cold beverages to hot beverages in the wintertime, and/or information gathered or supplied by a marketing program and/or by such customer when signing up or otherwise maintaining such information in a customer loyalty or other marketing program's database, or by importing or otherwise accessing information about such customer via any public or commercially accessible database and/or any combination of the foregoing information.

Customer Objective—includes any desired outcome, behavior that benefits a customer, including, for example, improved or better pricing, service, e.g., friendly service, speed of service, accuracy of service, quality of delivered products, types of marketing offers and/or savings associated with each, cleanliness of location, type of online or other ordering systems, including, e.g., POS devices, or any other favorable treatment or benefit that can be obtain or otherwise accrues to the benefit of such customer, and/or any combination of the foregoing.

Discount—includes any price or offer at an amount other than the standard list price or expected price or shelf price, or displayed price, e.g., online.

Display—includes any one or more of the following electronic devices including, but not limited to: TV (of any technology type, including but not limited to a Plasma Display, LCD, CRT or DLP), Kiosk, LED display, Electronic Shelf Label, Automated Teller Machine (ATM), POS terminal, video game display, video slot machine or other video based casino games, speaker, or any other device capable of displaying, presenting or otherwise outputting or processing Output Materials (such as an LCD or other display in an airline seatback or other Location, e.g., a grocery cart equipped with a display and/or a bar code or RFID printer or reader), including devices that provide a User with Output Functionality. A Display may include or be one or more of a Controller and/or a Server and/or other computing device capable of providing Input and/or Output Functionality and/or Remote Connectivity.

Domain Name Server (DNS)—One or more computers including a cooperatively run set of databases, distributed among several servers, volunteered as repositories for IP address information.

End User—includes any person or entity making use of any one or more of the methods of the disclosed invention, and/or any system that uses or is based upon or benefits from one or more of the disclosed inventions, including, for example, customers, vendors, retailers, QSR operators, managers, employees, supervisors, friends, family members, or any other person as applicable to the given context or otherwise.

Existing Member—includes a member of a loyalty program or other marketing program and/or a person that has signed up for any marketing or other program and/or has provided information to such a program, whether or not such person is aware of such program, including, end users.

Frequent Shopper Program—includes any system that provides one or more rewards to members of such program for purchases made.

Frequency Program—includes any Frequent Shopper Program or other rewards system that rewards customers for their frequency of visit and/or buying one or more products, goods or services.

GUI—includes a graphical user interface, or other means of providing communications from or to an end user, including via graphics, text, audio, video, data input, such as voice, typing, touch screen, or other means of input or output to/from any device, including a POS Terminal, or other computing devices. Such GUI may include information and/or actions that are available for viewing, use or interaction with an end user. Such interaction may be accomplished via any applicable means, including, for example, manipulating icons, widgets or other items or areas displayed on such GUI, including, clicking on one or more hyperlinks, and/or entering information into fields or other areas designed for such purposes, e.g., typing a name, or selecting one or more items from a displayed list, etc.

Header—A numeric code assigned to a request for content by either a LAN or ISP Server, which identifies a requestor's unique Internet Protocol Address. Generally, the Header is used for purposes of accurately returning a requested Mark-up Language-based electronic document as well as any corresponding files to the requestor.

Hyperlink—A text phrase or graphic embedded within a markup language-based electronic file, which corresponds to the address of a site on the World Wide Web.

Input Functionality—includes any one or more of any of the following, including but is not limited to any device that includes or provides one or more buttons (e.g., a keyboard) that can convey individual or grouped electrical signals, impulses, commands, or messages, or other tactile or other input device including a joy stick, mouse, touch screen, and/or audio (e.g., voice commands or instructions), bar code scanner, RFID reader, fingerprint or other biometric scanning device, scale, laser pointer, camera, infrared sensor, cell phone, hand held computer or PDA keypad, motion or other “presence” detector, magnetic card or magnetic card reader, and any other input method recognizable by or able to convey information to any one or more of a Display, Server, Controller or other computing device.

Internet—includes the world wide web and the network that is accessible by the public that includes a network of interconnected computers that transmit data using, for example, Internet Protocol (IP). In some aspects, certain private networks, including virtual private networks (VPN) may be included in the definition of the Internet.

Internet Device or Internet Enabled Device—includes any computing device that is capable of accessing or otherwise communicating with or via the Internet or any other network, client/server and/or peer-to-peer or any other network, and/or that is otherwise able to practice or benefit from any one or more of the herein disclosed inventions.

Internet Ordering or Online Purchase—includes the processing, in whole or in part, of any one or more transactions using or otherwise communicating via the Internet or other means of communications by or between any one or more of a business, sponsor and/or one or more customers, which transaction may be for or include the purchase, trade or acquisition of one or more items. In certain embodiments, internet ordering or online purchases may include the delivery of one or more marketing messages or marketing offers.

Item—includes any object, tangible or intangible, which may include any item for sale, rental, lease, consumption, transfer, and/or may be possessed or owned. Item may include any physical or virtual object. In certain embodiments an item may be any one or more of a food item, a beverage item, a dessert item, a retail good, a food product, a device, a POS device, a coupon, clothing, furnishings, groceries, automobiles, motorcycles, lighting, electrical equipment or devices, etc.

Kiosk—includes any device or location that permits a customer or end user to enter part or all of an order and/or respond to a marketing message or offer, with or without the assistance of a third party, e.g., a cashier. Kiosks may include software to prevent end users from performing unauthorized actions and/or accessing the system, operating system or other secure areas of the kiosk and/or systems to which it may be attached or connected, e.g., the Internet or one or more servers, etc.

Location—means and includes, but is not limited to retail stores, restaurants, bars, theme parks, casinos, video game parlors, Internet Café's, coffee bars, book stores, gas stations, convenience stores, hotel rooms, hotel or other lobbies, meeting rooms, office buildings, offices, airports, airplanes, government or other public services buildings, hospitals or any other public or private area or facility or residence that contains, possesses or otherwise provides limited or general access to at least one Display and/or practices part or all of any one or more embodiments of the present invention.

Loyalty or Frequent Shopper Member—includes any end user or person that has joined or signed up or opted into a loyalty program and/or frequent shopper program.

Loyalty Member—a person that has signed up for or otherwise participates in a loyalty or frequent shopper program.

Loyalty Program—any system that permits users to sign up to receive rewards based upon such user's purchases or visitation frequency.

Marketing Message—Includes a marketing offer, or any other communication with an end user, e.g., a customer, which message may include any one or more of the following such as, any one or more of a graphic, logo, icon, price, discount or other offer, video, audio, or other visual, audio or static marketing or other content designed to communicate with or otherwise inform, educate or persuade a User. In certain embodiments, a marketing message may include one or more marketing offers.

Marketing Offer or Offer—includes any offer for sale of any item, good, product or service.

Marketing Program—includes any system that provides marketing messages, marketing content, loyalty programs, coupons, discounts, or any other offers or marketing offers, and/or tracks customer buying habits and other information, including customer information, such as locations, travels, demographics, ordering preferences, etc.

Markup Language—A set of codes in a text file that instructs a computer how to format the file for purposes of printing and/or display, as well as how to index and link the content of the file. Example markup languages include HTML, SGML, XML, VRML, and NRML.

Network Device—includes any device that can be interfaced with a technology network, for example, the Internet, a wireless communications network, (e.g., a cellular telephone system), a LAN, or a WAN.

Optimized—includes determining which marketing offer will likely or generally achieve the desired results or maximum results among or given one or more of several complimentary or competing objectives, including, for example, sales volume, gross margin, profits, customer accept rates, average check, speed of service times, product quality, freshness, customer satisfaction, customer frequency, order point, destination point or any other variables that affect or are of interest to one or more affected parties, e.g., the retail establishment, its suppliers and/or the customer. In certain embodiments, optimized includes finding the maxima or minima of a given function. In certain embodiments, the terms optimized and optimal have corollary meanings.

Output functionality—includes transmission of information via Remote Connectivity and/or conveying Output Materials on a Display and/or tactile feedback.

Output Materials means any one or more of the following, including but is not limited to any one or more of, Marketing Messages, audio, still images and/or video, flash and/or other animated sequences or materials, printed or visual reports or receipts, displayed information, information recorded to or stored on a hard drive or other computer readable medium, a text message, voice mail message, a sound such as a beep or bell or buzzer, audio messages (e.g. a voice prompt or marketing message or other information), including recorded, actual or synthetic voice messages, or any other output generated by a Display, Server, Controller, Network or other device or application that is sent to or processed by a User, Display, Server, Controller, Network or other device for subsequent viewing, listening and/or further processing or storage.

PC—includes a personal computer, such as a laptop, such as one provided by Dell Computers.

PDA—includes a personal digital assistant, such as Palm Pilot, or any other personal computing device, which includes at least one of a display, processor, memory or input or output means.

Point of Sale—includes any Point of Sale system or device that permits an end user to start, enter or complete an order or sales transaction, such as Panasonic's 7900 “all in one”, or any other POS devices, terminals or systems, websites, kiosks, PCs, PDAs, Cell Phones, call centers, slot machines, vending machines, and/or any other Internet or other device that provides access to any of the functionality or inventions disclosed herein and or any of the same or similar functionality and/or otherwise permits an end user to practice or benefit from any of the disclosed inventions. Point of Sale and POS shall have corollary meanings.

POS Device, includes a POS or other physical device that provides access to any of the features or inventions disclosed herein and or any of the same or similar functionality and/or otherwise permits an end user to practice or benefit from any of the disclosed inventions.

POS Terminal—includes a POS or other physical device that provides access to any of the foregoing and or any of the same or similar functionality and/or otherwise permits an end user to practice or benefit from any of the disclosed inventions.

Product—includes any machine, manufacture and/or composition of matter, unless expressly specified otherwise.

Prospective Member—includes any person that is not currently a member.

Proximal, Proximity, Proximal/Proximity Data—includes any information about an end user's current or predicted whereabouts. Such information may include distance, i.e., distance between two points, e.g., a retail location and the end user, which distance may be measured directly, e.g., point A to point B, or based upon travel means, e.g., based upon the streets or other paths that a person or end user could actually use to travel from said point A to said point B, and/or may be based upon time, e.g., how long it might take a given end user to travel said distance between point A and point B, perhaps further as determined by such end user's current rate of travel or average rate of travel or method of travel, etc. Methods to calculate distances between to points in space and/or to estimate travel time are well known by those of ordinary skill in the art.

Reports—in certain of the disclosed embodiments, one or more reports may be developed to provide tracking and/or analysis relating to any one or more data elements associated with any such embodiment or invention. Reports include any feedback or communication requested by or delivered to one or more end users, which may or may not require authorization to receive such report. Reports can be printed, verbalized using a text to speech conversion program, or displayed on any device, including, for example, a POS terminal or other computing device. Such reports may be created and/or delivered using any applicable means available. The methods to create and deliver reports are well understood and known within the industry and are disclosed in the prior art. Reports may be demand request, i.e., a report is generated only when or as requested, or exception based, i.e., a report is generated if a certain condition or conditions are met, not met or change in any defined way. In certain embodiments, reports are generated whenever desired or otherwise indicated or scheduled, and may be stored for subsequent use, which use may or may not be based on a request by an end user. Reports may include any one or more available database elements and/or calculated results based upon any one or more of the databases, database elements, mathematical or statistical manipulations, and/or any of the methods disclosed herein and/or as understood by any person skilled in the art and/or as requested/designed by one or more end users or other authorized personnel. For example, a report may include any one or more pieces of information contained or relating to customer, business or sponsor information, and/or POS transaction data and/or any or all results information generated or associated with any marketing offer or message.

RFID—includes a radio frequency identification tag, transponder or similar devices.

Router—An intermediary device within a communications network that expedites message delivery. Within a single network linking many computers through several possible connections, a router receives transmitted messages and forwards them to their correct destination via an efficient available route.

Sensor—includes any application or device that can make a determination or otherwise detecting the change, presence or absence of something, including, for example, temperature, weight, sound, pressure, volume, mass, light, odors, and/or any recording, or registration, change, presence or absence of or to any data or other electronic media. In certain embodiments a sensor includes one or more transducers.

Store/retail location—includes any one or more retail, restaurant or other location, and may include online locations, websites, kiosks, automated stores, e.g., vending machines, so called “brick and mortar” locations, and/or any combination of the foregoing, and/or access to any such location(s) using any POS device.

Tag—A code embedded within an markup language-based electronic file which associates one or more words or images within the document with a Uniform Resource Locator (URL) corresponding to another file. Within the art, a tag of this particular functionality may be referred to as an “HREF” (hypertext reference) tag.

Transaction—includes any communication or agreement between two or more entities, including end users, individuals, retailers, and/or computing systems. In certain embodiments a transaction can include a financial transaction wherein a seller sells and item and a buy buys an item, where such seller may experience an increase in finances while the buyer's finances may decrease. In certain embodiments, a transaction may include a communication between a computing system and an one or more end users, or between two computing systems, a computing system and a database or data repository, two end users, two or more data repositories, etc. In additional embodiments, a transaction includes a POS transaction, where a customer places and pays for one or more items, goods, services, or products and/or access to or use of any or all of the foregoing, and/or via a website and/or using a POS terminal or POS device.

User—includes any entity or person including a person making use or practicing the various disclosed embodiments of the invention. The terms user and end user shall include corollary meanings.

User-Visible Text Portion—A portion of markup language-based code which specifies the text or other images to be displayed to a Web user. An example (in bold) as well as the corresponding tag (underlined) follows: Ex. <A HREF=“http://go.msn.com/npl/msnt.asp” target=“_top”><IMG_SRC=“/chan/home/logo.gif” WIDTH=140 HEIGHT=60 BORDER=0 ALT=“Go to msn.com”>Microsoft Network</A>

Web Browser—A client application that enables a user to view markup language-based documents on the World Wide Web, another network, or the user's computer; utilize the hyperlinks among the documents, as well as transfer and execute files within the documents.

Web Site—A subset of the World Wide Web comprising a collection of files, documents and graphics made generally available to others through the Internet. In certain embodiments a web site may include means for conducting a transaction, including, for example, a POS transaction.

Wireless Communications Device (WCD)—A communications device that transceives via a non-wired medium, such as radio frequency. A WCD can include, but is not limited to an AM or FM radio device, a television, cell phones, portable phones, and devices, such as laptop computers and PDAs interfaced with a wireless network, for example, a LAN. Applicable formats, standards or protocols, include Ethernet (or IEEE 802.3), SAP, ATP, Bluetooth, and TCP/IP, TDMA, CDMA, and 3G.

World Wide Web—The total set of inter-linked hypertext documents residing on Hypertext

Disclosed Examples and Terminology Are Not Limiting. Numerous embodiments are described in this patent application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural, logical, software, and electrical or electromechanical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

The present disclosure is neither a literal description of all embodiments of the invention nor a listing of features of the invention which must be present in all embodiments. plication are for convenience only, and are not to be taken as limiting the disclosure in any way.

Devices that are described as in communication or otherwise connected with each other need not be in continuous communication or connection with each other, unless expressly specified otherwise. On the contrary, such devices need only transmit or be otherwise connected to each other as necessary or desirable, and may actually refrain from exchanging data or electrical current most of the time. For example, a machine in communication with another machine via the Internet may not transmit data to the other machine for a prolonged period (e.g. weeks at a time). In addition, devices that are in communication with each other may communicate directly or indirectly through one or more intermediaries.

A description of an embodiment with several components or features does not imply that all or even any of such components/features are required. On the contrary, a variety of optional components are described to illustrate the wide variety of possible embodiments of the present invention(s). Unless otherwise specified explicitly, no component/feature is essential or required.

Although process steps, algorithms or the like may be described in a sequential order, such processes may be configured to work in different orders. In other words, any sequence or order of steps that may be explicitly described does not necessarily indicate a requirement that the steps be performed in that order. On the contrary, the steps of processes described herein may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to the invention, and does not imply that the illustrated process is preferred.

Although a process may be described as including a plurality of steps, that does not imply that all or any of the steps are essential or required. Various other embodiments within the scope of the described invention(s) include other processes that omit some or all of the described steps. Unless otherwise specified explicitly, no step is essential or required.

Although a product may be described as including a plurality of components, aspects, qualities, characteristics and/or features, that does not indicate that all of the plurality are essential or required. Various other embodiments within the scope of the described invention(s) include other products that omit some or all of the described plurality.

Unless expressly specified otherwise, an enumerated list of items (which may or may not be numbered) does not imply that any or all of the items are mutually exclusive. Therefore it is possible, but not necessarily true, that something can be considered to be, or fit the definition of, two or more of the items in an enumerated list. Also, an item in the enumerated list can be a subset (a specific type of) of another item in the enumerated list. For example, the enumerated list “a computer, a laptop, a PDA” does not imply that any or all of the three items of that list are mutually exclusive—e.g., an item can be both a laptop and a computer, and a “laptop” can be a subset of (a specific type of) a “computer”.

Likewise, unless expressly specified otherwise, an enumerated list of items (which may or may not be numbered) does not imply that any or all of the items are collectively exhaustive or otherwise comprehensive of any category. For example, the enumerated list “a computer, a laptop, a PDA” does not imply that any or all of the three items of that list are comprehensive of any category. Further, an enumerated listing of items does not imply that the items are ordered in any manner according to the order in which they are enumerated.

Computing. It will be readily apparent to one of ordinary skill in the art that the various processes described herein may be implemented by, e.g., appropriately programmed general purpose computers and computing devices. Typically a processor (e.g., one or more microprocessors, one or more microcontrollers, one or more digital signal processors) will receive instructions (e.g., from a memory or like device), and execute those instructions, thereby performing one or more processes defined by those instructions. A “processor” means one or more microprocessors, central processing units (CPUs), computing devices, microcontrollers, digital signal processors, or like devices or any combination thereof.

Thus a description of a process is likewise a description of an apparatus for performing the process. The apparatus can include, e.g., a processor and those input devices and output devices that are appropriate to perform the method. Further, programs that implement such methods (as well as other types of data) may be stored and transmitted using a variety of media (e.g., computer readable media) in a number of manners. In some embodiments, hard-wired circuitry or custom hardware may be used in place of, or in combination with, some or all of the software instructions that can implement the processes of various embodiments. Thus, various combinations of hardware and software may be used instead of software or hardware only.

The term “computer-readable medium” refers to any medium that participates in providing data (e.g., instructions, data structures) which may be read by a computer, a processor or a like device. Such a medium may take many forms, including but not limited to, non-volatile media, volatile media, and transmission media. Non-volatile media include, for example, optical or magnetic disks and other persistent memory. Volatile media include dynamic random access memory (DRAM), which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, a carrier wave as described hereinafter, or any other medium from which a computer can read.

Various forms of computer readable media may be involved in carrying data (e.g. sequences of instructions) to a processor. For example, data may be (i) delivered from RAM to a processor; (ii) carried over a wireless transmission medium; (iii) formatted and/or transmitted according to numerous formats, standards or protocols, such as Ethernet (or IEEE 802.3), SAP, ATP, Bluetooth, and TCP/IP, TDMA, CDMA, and 3G; and/or (iv) encrypted to ensure privacy or prevent fraud in any of a variety of ways well known in the art.

Thus a description of a process is likewise a description of a computer-readable medium storing a program for performing the process. The computer-readable medium can store (in any appropriate format) those program elements which are appropriate to perform the method.

Just as the description of various steps in a process does not indicate that all the described steps are required, embodiments of an apparatus include a computer/computing device operable to perform some (but not necessarily all) of the described process.

Likewise, just as the description of various steps in a process does not indicate that all the described steps are required, embodiments of a computer-readable medium storing a program or data structure include a computer-readable medium storing a program that, when executed, can cause a processor to perform some (but not necessarily all) of the described process.

Where databases are described, it will be understood by one of ordinary skill in the art that (i) alternative database structures to those described may be readily employed, and (ii) other memory structures besides databases may be readily employed. Any illustrations or descriptions of any sample databases presented herein are illustrative arrangements for stored representations of information. Any number of other arrangements may be employed besides those suggested by, e.g., tables illustrated in drawings or elsewhere. Similarly, any illustrated entries of the databases represent exemplary information only; one of ordinary skill in the art will understand that the number and content of the entries can be different from those described herein. Further, despite any depiction of the databases as tables, other formats (including relational databases, object-based models and/or distributed databases) are well known and could be used to store and manipulate the data types described herein. Likewise, object methods or behaviors of a database can be used to implement various processes, such as the described herein. In addition, the databases may, in a known manner, be stored locally or remotely from any device(s) which access data in the database.

Various embodiments can be configured to work in a network environment including a computer that is in communication (e.g., via a communications network) with one or more devices. The computer may communicate with the devices directly or indirectly, via any wired or wireless medium (e.g. the Internet, LAN, WAN or Ethernet, Token Ring, a telephone line, a cable line, a radio channel, an optical communications line, commercial on-line service providers, bulletin board systems, a satellite communications link, a combination of any of the above). Each of the devices may themselves comprise computers or other computing devices, such as those based on the Intel® Pentium® or Centrino™ processor, that are adapted to communicate with the computer. Any number and type of devices may be in communication with the computer.

Remote Connectivity means any method used by a Controller, a Display or a Server or other computing devices to communicate with other devices or networks including, but not limited to the Internet, Satellite networks, Cell Phone networks, other wireless networks and standards such as 802.11, 80211.b, 802.11g, or similar wireless LAN operating standards, or Bluetooth technologies, infrared connections, or any other similar technologies or other technologies such as those described above that permit the sending and/or receiving and/or processing of electronic information in either an encrypted or unencrypted format.

Server means one or more computing systems that include at least one of a processor, computer readable medium, or input/output capabilities and may have local or Remote Connectivity capabilities. Servers may be local or remote to Displays or both. A Server may be or include one or more of a Display and/or a Controller.

In an embodiment, a Server computer or centralized authority may not be necessary or desirable. For example, the present invention may, in an embodiment, be practiced on one or more devices without a central authority. In such an embodiment, any functions described herein as performed by the Server computer or data described as stored on the Server computer may instead be performed by or stored on one or more such devices.

Disclaimer. Numerous references to a particular embodiment does not indicate a disclaimer or disavowal of additional, different embodiments, and similarly references to the description of embodiments which all include a particular feature does not indicate a disclaimer or disavowal of embodiments which do not include that particular feature.

Rules of Interpretation. Numerous embodiments are described in this disclosure, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural, logical, software, and electrical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise. The present disclosure is neither a literal description of all embodiments nor a listing of features of the invention that must be present in all embodiments.

The functionality and/or the features of a single device that is described may be alternatively embodied by one or more other devices that are described but are not explicitly described as having such functionality and/or features. Thus, other embodiments need not include the described device itself, but rather can include the one or more other devices which would, in those other embodiments, have such functionality/features.

Devices that are in communication with each other need not be in continuous communication with each other, unless expressly specified otherwise. On the contrary, such devices need only transmit to each other as necessary or desirable, and may actually refrain from exchanging data most of the time. For example, a machine in communication with another machine via the Internet may not transmit data to the other machine for weeks at a time. In addition, devices that are in communication with each other may communicate directly or indirectly through one or more intermediaries.

“Determining” something can be performed in a variety of manners and therefore the term “determining” (and like terms) includes calculating, computing, deriving, looking up (e.g., in a table, database or data structure), ascertaining, recognizing, and the like. A “display” as that term is used herein is an area that conveys information to a viewer. The information may be dynamic, in which case, an LCD, LED, CRT, LDP, rear projection, front projection, or the like may be used to form the display. The aspect ratio of the display may be 4:3, 16:9, or the like. Furthermore, the resolution of the display may be any appropriate resolution such as 480i, 480p, 720p, 1080i, 1080p or the like. The format of information sent to the display may be any appropriate format such as standard definition (SDTV), enhanced definition (EDTV), high definition (HD), or the like. The information may likewise be static, in which case, painted glass may be used to form the display. Note that static information may be presented on a display capable of displaying dynamic information if desired.

The present disclosure may refer to a “control system”. A control system, as that term is used herein, may be a computer processor coupled with an operating system, device drivers, and appropriate programs (collectively “software”) with instructions to provide the functionality described for the control system. The software is stored in an associated memory device (sometimes referred to as a computer readable medium). While it is contemplated that an appropriately programmed general purpose computer or computing device may be used, it is also contemplated that hard-wired circuitry or custom hardware (e.g., an application specific integrated circuit (ASIC)) may be used in place of, or in combination with, software instructions for implementation of the processes of various embodiments. Thus, embodiments are not limited to any specific combination of hardware and software.

A “processor” means any one or more microprocessors, CPU devices, computing devices, microcontrollers, digital signal processors, or like devices. Exemplary processors are the INTEL PENTIUM or AMD ATHLON processors. The term “computer-readable medium” refers to any medium that participates in providing data (e.g., instructions) that may be read by a computer, a processor or a like device. Such a medium may take many forms, including but not limited to, non-volatile media, volatile media, and transmission media. Non-volatile media include, for example, optical or magnetic disks and other persistent memory. Volatile media include DRAM, which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during RF and IR data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, a USB memory stick, a dongle, any other memory chip or cartridge, a carrier wave as described hereinafter, or any other medium from which a computer can read.

Various forms of computer readable media may be involved in carrying sequences of instructions to a processor. For example, sequences of instruction (i) may be delivered from RAM to a processor, (ii) may be carried over a wireless transmission medium, and/or (iii) may be formatted according to numerous formats, standards or protocols. For a more exhaustive list of protocols, the term “network” is defined below and includes many exemplary protocols that are also applicable here.

It will be readily apparent that the various methods and algorithms described herein may be implemented by a control system and/or the instructions of the software may be designed to carry out the processes of the present invention.

Where databases are described, it will be understood by one of ordinary skill in the art that (i) alternative database structures to those described may be readily employed, and (ii) other memory structures besides databases may be readily employed. Any illustrations or descriptions of any sample databases presented herein are illustrative arrangements for stored representations of information. Any number of other arrangements may be employed besides those suggested by, e.g., tables illustrated in drawings or elsewhere. Similarly, any illustrated entries of the databases represent exemplary information only; one of ordinary skill in the art will understand that the number and content of the entries can be different from those described herein. Further, despite any depiction of the databases as tables, other formats (including relational databases, object-based models, hierarchical electronic file structures, and/or distributed databases) could be used to store and manipulate the data types described herein. Likewise, object methods or behaviors of a database can be used to implement various processes, such as those described herein. In addition, the databases may, in a known manner, be stored locally or remotely from a device that accesses data in such a database. Furthermore, while unified databases may be contemplated, it is also possible that the databases may be distributed and/or duplicated amongst a variety of devices.

As used herein a “network” is an environment wherein one or more computing devices may communicate with one another. Such devices may communicate directly or indirectly, via a wired or wireless medium such as the Internet, LAN, WAN or Ethernet (or IEEE 802.3), Token Ring, or via any appropriate communications means or combination of communications means. Exemplary protocols include but are not limited to: Bluetooth™, TDMA, CDMA, GSM, EDGE, GPRS, WCDMA, AMPS, D-AMPS, IEEE 802.11 (WI-FI), IEEE 802.3, SAP, SAS™ by IGT, OASIS™ by Aristocrat Technologies, SDS by Bally Gaming and Systems, ATP, TCP/IP, gaming device standard (GDS) published by the Gaming Standards Association of Fremont Calif., the best of breed (BOB), system to system (S2S), or the like. Note that if video signals or large files are being sent over the network, a broadband network may be used to alleviate delays associated with the transfer of such large files, however, such is not strictly required. Each of the devices is adapted to communicate on such a communication means. Any number and type of machines may be in communication via the network. Where the network is the Internet, communications over the Internet may be through a website maintained by a computer on a remote server or over an online data network including commercial online service providers, bulletin board systems, and the like. In yet other embodiments, the devices may communicate with one another over RF, cable TV, satellite links, and the like. Where appropriate encryption or other security measures such as logins and passwords may be provided to protect proprietary or confidential information.

Communication among computers and devices may be encrypted to insure privacy and prevent fraud in any of a variety of ways well known in the art. Appropriate cryptographic protocols for bolstering system security are described in Schneier, APPLIED CRYPTOGRAPHY, PROTOCOLS, ALGORITHMS, AND SOURCE CODE IN C, John Wiley & Sons, Inc. 2d ed., 1996, which is incorporated by reference in its entirety.

The present disclosure provides, to one of ordinary skill in the art, an enabling description of several embodiments and/or inventions. Some of these embodiments and/or inventions may not be claimed in the present disclosure, but may nevertheless be claimed in one or more continuing applications that claim the benefit of priority of the present disclosure.

It will, of course, be understood that the foregoing description is of exemplary embodiments of the invention and that the invention is not limited to the specific embodiments shown. Various changes and modifications will become apparent to those skilled in the art and all such variations and modifications are intended to come within the spirit and scope of the appended claims.

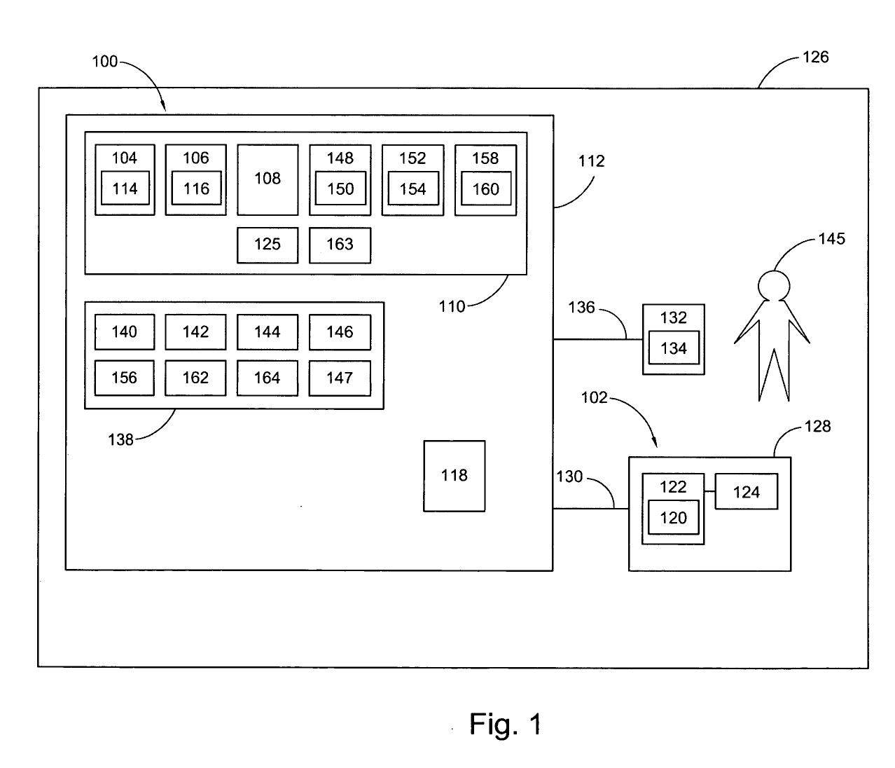

FIG. 1 is a schematic block diagram of present invention system 100 for adjusting volume for a kiosk in marketing, or selling, system 102. Marketing system and selling system are used interchangeable infra. System 100 includes parameter determination element, or function, 104, generating element, or function, 106, and control element, or function, 108, each of which is in processor 110 of at least one specially programmed general-purpose computer 112. Alternately stated, elements 104, 106, and 108 and any other elements described as being in the processor are functions of the processor or are functions carried out by the processor. Element 104 is arranged to determine parameter 114 associated with the selling system. The generating element is arranged to generate volume control level 116 based on parameter 114. The control element is arranged to control, via interface element 118 for the computer, audio output portion 120 of marketing, or sales, offer 122 from audio component 124 of the selling system such that the audio output portion matches the volume control level. That is, the volume level of an audio message broadcast by component 124 is determined by and made equal to level 116. In one embodiment, sales offer 122 is generated by system 102. In another embodiment, offer 122 is generated by system 100, for example, by offer element 125 in the processor, and transmitted to system 102 via the interface element. In a further embodiment, the sales offer is generated by a system (not shown) separate from systems 100 and 102.

By interface element, we mean any combination of hardware, firmware, or software in a computer used to enable communication or data transfer between the computer and a device, system, or network external to the computer, for example, system 102. The interface element can connect with the device, system, or network external to the computer using any means known in the art, including, but not limited to a hardwire connection, an optical connection, an Internet connection, or a radio frequency connection. Processor 110 and interface element 118 can be any processor or interface element, respectively, or combination thereof, known in the art.

Computer 112 can be any computer or plurality of computers known in the art. In one embodiment, the computer is located in a retail location in which the selling system is located, for example, location 126. In another embodiment (not shown), all or parts of the computer are remote from the retail location. In a further embodiment (not shown) computer 112 is associated with more than one retail location, that is, the computer provides the functionality described at more than one retail location. It should be understood that a single system 100 can be connected to and operate more than one system 102 in a single location or more than one system 102 in more than one retail location.

Selling system 102 can be, but is not limited to, a point of sale (POS) system or wireless communications device. The POS system can be, but is not limited to, a register at a counter, a drive though display, a self-service kiosk, or any customer facing display and/or any speakers. The selling system 102 can be speakers placed throughout a retail establishment, for example, retail location 126. In a first embodiment, selling system 102 is self-serve kiosk 128 with hardwire connection 130 to system 100. In the preferred embodiment, computer 112 is separate from system 102.

In a preferred embodiment, the parameter is an ambient noise level proximate the selling system and system 100 includes noise sensing element 132 arranged to generate and transmit signal 134 proportional to an ambient noise level proximate the selling system. Element 132 can be any noise sensing sensor known in the art. Element 132 can be free-standing or can be incorporated in a housing or other structure for the selling system, for example, the sensor is a microphone in the kiosk. The parameter determination element is arranged to accept signal 134 via the interface element. The interface element is connected with the sensing element using any means known in the art, including, but not limited to a hardwire connection, an optical connection, an Internet connection, or a radio frequency connection. In the figures, a non-limiting example, of hardwire connection 136 is shown.

In a first embodiment, the parameter is a temporal parameter and the parameter determination element is arranged to determine a current, or applicable, temporal parameter. That is, the parameter is based on time, for example, a time of day and/or a day of week. Element 104 can determine a current temporal parameter using any means known in the art. In one embodiment an algorithm is used to generate level 116 according to a temporal parameter. In another embodiment, system 100 includes memory element 138 with electronic schedule 140 stored in the memory element. The schedule correlates various temporal metrics with applicable volume control levels. Parameter 116 is selected according to the schedule. For example, an operator (e.g., manager or employee or other person(s) so designated) of system 100 can develop schedule 140 of times/days or dates and corresponding volume control levels. For example, it may be desirable to have a lower volume level at the selling system late at night, but a higher volume level during the middle of the day. In another example, a store manager may want the volume higher during peak sales periods but lower at all other times. Thus, element 108 controls component 122 according to the respective times and volume control levels in the schedule. Memory element 138 can be any memory element known in the art.

In a second embodiment, the parameter is a volume of transactions, or other operational metric, during a specified time period in retail location 126 and the parameter determination element is arranged to determine the volume of transactions using any means known in the art. The specified time period can be a current time or a previous period of time. System 100 can measure the number of transactions, other customer or location information, or any combination thereof. Transactions can be measured by number of customer checks, number of items ordered, number of items sold or prepared, check amounts, averages of any of the preceding criteria, or any other criteria based upon one or more of any customer or business information that establishes an approximate correlation between sales activity and/or customer traffic and noise levels. System 100 adjusts the volume of component 124 accordingly. In one embodiment an algorithm is used to generate level 116 according to the volume of transactions or other operational metric. In another embodiment, adjustments are pre-established, for example, memory element 138 includes matrix 142 correlating transaction volumes or other operational metrics with volume control levels. In a further embodiment, appropriate volume levels, given transaction volumes or other operational metrics, are determined by a combination of user defined rules and artificial intelligence, for example, as disclosed by commonly-owned U.S. patent application labeled “METHOD AND SYSTEM FOR GENERATING, SELECTING, AND RUNNING EXECUTABLES IN A BUSINESS SYSTEM UTILIZING A COMBINATION OF USER DEFINED RULES AND ARTIFICIAL INTELLIGENCE,” inventors Otto et al., filed Nov. 9, 2007, which application is incorporated by reference herein.

In a third embodiment, system 102 is a POS device, such as a register, operated by personnel and the parameter is the identity of personnel operating the POS device. System 100 adjusts volume based on the identity of the particular cashier, call center operator, or other personnel operating the POS device. The parameter determination element is arranged to identify the personnel using any means known in the art. Thus, system 100 can be configured to have different volume settings for each cashier profile registered in the system. In one embodiment, the adjustments or settings are stored in table 144 in memory element 138, which correlates volume control levels with various personnel. In another embodiment, the volume control level is adjustable by the personnel operating the POS device using any means known in the art.

In a fourth embodiment, the parameter is the identity of customer 145 engaged with, or using, the selling system and the parameter determination element is arranged to identify the customer. Then, customer defined levels are used for the volume control levels. That is, volume control levels are selected based on customer defined preferences or directives associated with the identity of the customer. In one embodiment, the identities and appropriate volume control levels are stored in matrix, or table, 146 in the memory element. The customer can be identified by any means known in the art. In another embodiment, customers 145 identify themselves using overt actions, such as, by swiping a card, for example, by presenting a loyalty program card to system 102. In a further embodiment, a customer is identified by use of a frequent shopper, loyalty program or credit card to make a purchase (engage system 102). In yet another embodiment, in addition to or in the alternative to providing such identification means overtly, customers identify themselves passively, including, for example, by providing a cell phone number, GPS identification number or IP address, and/or a license plate number. In a still further embodiment, settings in table 146 are established by the customer in advance of a transaction with system 102, for example, as part of the process of signing up for a loyalty program.

In another embodiment, system 100 uses the identification of the customer to retrieve information 147 about the customer, for example, customer, business, or sponsor information, which information is further used to better or optimally determine an appropriate offer 122 and volume control setting. Such information can be located in memory element 138 or in a separate computer system (not shown).

As an example, a customer can indicate a preference to have a volume setting of a minimum of 3 (on a scale of 1 to 10 with 10 being the highest setting) and a maximum of 7. Such settings are then adjusted based upon any one or more other factors, including, for example, ambient noise. For example, in a high ambient noise situation, the upper level of the preferred level is selected. Such adjustments or settings may be absolute, for example, a customer prefers a certain volume setting when engaged with system 102 inside location 126 and a higher volume setting when at a drive through (not shown) for the location. Such adjustments or settings also may be variable. For example, a customer prefers a slightly lower volume setting than whatever the prevailing setting is, but never less than one value or higher than another value. In another example, a customer might include such minimums or maximums by device type, ordering point, retail brand name, or specific store locations. In another example, a customer may set a single volume setting. Thus, the parameter determination element is arranged to use a volume preference for the customer, retrieved from table 146, as the volume control level. In another embodiment, system 100 associates volume levels with groups of frequent shoppers based on characteristics (or profiles) shared by the groups. For example, all customers over age 60 receive offers 120 at a specified volume control level.

In a further embodiment, the customer can establish or modify volume level preferences via system 102. For example, query element 148 in the processor is arranged to transmit, using the interface element, query 150 to the selling system for presentation to the customer regarding a preferred volume level. Response element 152 in the processor is arranged to create or modify table 146 using response 154 to the query received via the interface element.

In a fifth embodiment, system 102 includes a plurality of devices (not shown) disposed in different spots within a location or locations and parameter 114 is the different positions of the devices. For example, system 102 could include a register at a walk-up counter, a drive through arrangement, and a self-service kiosk. Table, or matrix, 156 in the memory element can include respective volume control settings for each of the devices and element 108 can control the devices accordingly.

In a sixth embodiment, system 100 includes manual override element 158 in the processor that is accessible, for example, by management and/or staff at or associated with location 126 to adjust or override temporarily or permanently the volume control lever for one or more or all of the devices in system 102. Such control can be implemented in any way known in the art. In one embodiment, the manual override element is under additional security control methods, such as, but not limited to a password, user identification, fingerprint scan, or other form of security. In another embodiment, such override capabilities can be adjusted remotely, for example, via the Internet (not shown), again, with or without added security.

In a further embodiment, the duration of manual override 160 is selectable, that is, the short or long term affect upon the initial or subsequently determined settings can be selected manually or automatically. For example, durations for overrides, for example based on when the overrides occur, which device in system 102 is affected, and which personnel make the override, can be stored in table 162 in the memory element. In yet another embodiment, element 158 evaluates the manual overrides to automatically adapt the system to these overrides. For example, if the management or staff at location 126 continually uses the manual override element to lower certain volume control levels, system 100 adjusts the upper end of the control levels so as not to exceed any such manual adjustment levels. For example, volume control levels in table 142 can be adjusted according to override 160 to reflect preferences in retail establishment 126.

As an example, a night shift may prefer a generally louder setting than a day shift. By tracking which personnel, for example at location 126, make certain changes over time, system 100 can learn which settings to apply during various time periods, for example, each shift, day, day of the week. For example, by tracking overrides associated with a particular manager, the system can automatically apply the overrides when the manager is on duty. Such learning and/or changes might be applied as absolutes, for example, a specific sound setting, or in relative terms, for example, when the system determines that the loudest setting is required, the system further determines an “adjustment factor” either louder or softer, depending upon tracking of manual adjustments.

In a seventh embodiment, parameter 114 is profitability and level 116 is selected to optimize profitability using a rules based system, a table driven system, expert (e.g. human) system, or an artificial intelligence system, for example, such as disclosed by commonly-owned U.S. patent application labeled “METHOD AND SYSTEM FOR GENERATING, SELECTING, AND RUNNING EXECUTABLES IN A BUSINESS SYSTEM UTILIZING A COMBINATION OF USER DEFINED RULES AND ARTIFICIAL INTELLIGENCE,” inventors Otto et al., filed Nov. 9, 2007. For example, evaluation element 163 in the processor evaluates any metric known in the art associated with profitability, including but not limited to offer acceptance, transaction profit, average check, transaction speed, or any combination thereof, in light of various volume control levels. Elements 104, 106, and 163 interact so that a volume control level that optimizes profitability is selected and modified as needed. For example, for a same time period and ambient noise level, system 100 can provide different volume control levels and determine which, if any, of the different levels results in the highest profitability and then use that level when the time period and ambient noise level are repeated. In one embodiment, the determination of profitability and subsequent system 100 adjustments are carried out continually or periodically.

Also, element 163 can monitor manual overrides and determine if a manual override is causing a negative effect on profitability metrics. For example, for a same time period and ambient noise level, system 100 can compare profitability when manual overrides are not present and profitability when manual overrides are present. System 100 also can evaluate a plurality of manual overrides to categorize or rank the overrides in terms of negative effects on profitability. In one embodiment, if a negative effect on profitability is detected, system 100 issues an message alerting appropriate personnel and providing applicable detail regarding the override or overrides in question, for example, the type of override, the magnitude of the override, and other conditions or metrics associated with the override. The message is presented or displayed using any means known in the art. In another embodiments, element 163 automatically interfaces with system 100 to modify manual overrides to reduce or eliminate losses of profitability associated with the overrides. For example, such overrides can be blocked by system 100.

It should be understood that the various embodiments described supra can be combined. Any combination of various embodiments is included within the spirit and scope of the claimed invention. For example, at a single location 126, volume levels for a drive through POS device (not shown) can be adjusted based upon the time of day, to coincide with road traffic levels, while inside, volume levels at a counter register (not shown) can be adjusted based upon the ambient noise and a given cashier's preferences. Combinations of the various embodiments can be determined by a combination of user defined rules and artificial intelligence, for example, as disclosed by commonly-owned U.S. patent application labeled “METHOD AND SYSTEM FOR GENERATING, SELECTING, AND RUNNING EXECUTABLES IN A BUSINESS SYSTEM UTILIZING A COMBINATION OF USER DEFINED RULES AND ARTIFICIAL INTELLIGENCE,” inventors Otto et al., filed Nov. 9, 2007.

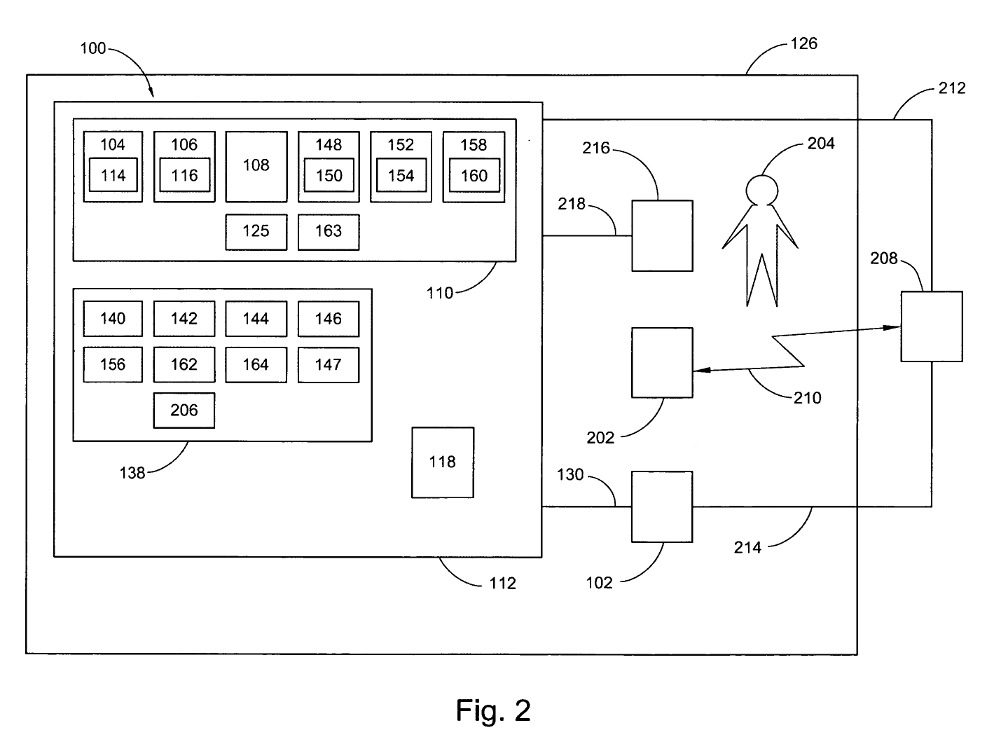

FIG. 2 is a schematic block diagram of present invention system 100 for adjusting volume for wireless communications device (WCD) 202 interfaced with selling system 102. A WCD is defined supra. WCD 202 can be any WCD known in the art. In general, the WCD serves as an extension of system 102 and provides a remote audio/visual display for system 102. In one embodiment, a person, for example, customer 204, entering location 126 is provided with WCD 202, for example, by an entity operating the location. In one embodiment, WCD 202 is owned by, leased by, or otherwise already in possession of customer, or end user, 204 when the end user enters the retail location. In general, a person in physical possession of device 202 is referred to as an end user and an end user is assumed to be an owner of device 202 or a person authorized by the owner of device 202 to use the device or is otherwise in current possession of such device. Alternately stated, the end user is associated with device 202, by which we mean that the device is owned by the end user, registered to or otherwise controlled by the end user, or otherwise linked to the end user such that an identification of the device enables authorized identification of the end user. In one embodiment, the end user is a known customer of a business entity (not shown) associated with the retail location. For example, the end user is registered with the business entity or the retail location. The registration can be in the form of a loyalty program or similar arrangement. In another embodiment, memory element 138 includes data 206 regarding the customer and device 202, for example, customer information as defined supra. In a further embodiment, computer 100 has access to a remote memory element (not shown) containing data regarding the customer, which information may include customer information or objectives.

In general, the WCD communicates with a network, for example, network 208, via radio-frequency connection 210. Network 208 can be any network known in the art. In one embodiment, the network is located outside of the retail location, for example, the network is a commercial cellular telephone network or WAN. In another embodiment (not shown), the network is located in the retail location, for example, the network is a LAN, such as a Bluetooth network or an infrared enabled system. The interface element and system 102 can connect with network 208 using any means known in the art, including, but not limited to a hardwire connection, an optical connection, an Internet connection, or a radio frequency connection. In the figures, non-limiting examples of hardwire connections 212 and 214, respectively, are shown.

In one embodiment, the wireless device is configured or provided with hardware or software (not shown) to enable system 100 to identifying the entry of the device into retail location 126. In another embodiment, device 202 is connectable to docking station 216, to enable device 202 to establish communication with system 100. That is, when the device is connected to the docking station, a link is established between the device and system 100. Any docking station or docking means known in the art can be used. The docking station is interfaced with element 118 using any means known in the art, including, but not limited to a hardwire connection, an optical connection, an Internet connection, or a radio frequency connection. In the figures, a non-limiting example of a hardwire connection 218 is shown. In a further embodiment, the WCD is disposed in a location different that a retail location (not shown) and the WCD connects to systems 100 and 102 via network 208. In general the discussion regarding the operation of system 100 in FIG. 1 is applicable to FIG. 2. For example, volume control levels for an audio output of offer 122 from the WCD are determined according to parameter 114 and element 108 controls the audio output of the WCD via the applicable network. Offer 122 is generated as described for FIG. 1 and transmitted to the WCD via the applicable network.

When parameter 114 is an ambient noise level, noise sensing element 132 can be a microphone in the WCD. When parameter 114 is the identity of the customer engaged with, or using, the selling system, the identity of the customer can be identified via the WCD, for example, the end user to whom the WCD is registered.

It should be understood that sales, or marketing, offer 122 can be any sales offer or marketing offer known in the art, for example, including a suggestive sales offer. In one embodiment, suggestive sales offers are generated as disclosed by commonly-owned U.S. patent application labeled “METHOD AND SYSTEM FOR GENERATING, SELECTING, AND RUNNING EXECUTABLES IN A BUSINESS SYSTEM UTILIZING A COMBINATION OF USER DEFINED RULES AND ARTIFICIAL INTELLIGENCE,” inventors Otto et al., filed Nov. 9, 2007.

The following should be viewed in light of FIGS. 1 and 2. System 100 can be a display with speakers mounted in front of or near a POS terminal, a POS terminal in a retail establishment, a self order entry kiosk in a retail establishment, the stereo system of a retail establishment or a car, a car's GPS system, a vending machine, a drive thru menu board or order confirmation unit in a quick serve restaurant, a self order check out system in a supermarket, a slot machine, a credit card authorization terminal, a Catalina type coupon printer, personal computer, a cell phone, PDA device, and/or a phone headset and/or any device that includes at least one speaker.

System 100 can control volume at the selling system on a transaction-by-transaction or other periodic basis. For a system 102 with multiple devices (not shown), system 100 can control volume individually, or, alternatively, all devices can be adjusted at the same time and/or at the same level, for example, as in the case of a front counter group of registers or POS terminals. In addition or in the alternate, system 100 can be designed so that changes occur either in one or multiple steps, for example, system 100 gradually increase or decrease respective volume levels so that such adjustments are nearly imperceptible to casual listeners.

Offer 122 can include any one or more of, but is not limited to, the following: a greeting, an offer for an additional or replacement product, a thank you message, a confirmation of part or all of the customer's order and/or changes made to such an order, a confirmation of the customer's subtotal, amount of payment received and/or change due, tax amounts (inclusive or exclusive) levied or collected, a general message, marketing message(s) or promotions, loyalty or marketing program name, status, points, message, or greeting. The offer also can include, but is not limited to, a confirmation of the amount of time a transaction took to process, or any other communication that is dynamically generated and/or statically recorded, or any combination of the foregoing messages or message types, and/or any other audible sound, such as a bell, chime, tone, ringer, or music. In one embodiment, the type of offer 122 is parameter 114 and the sound control level is selected accordingly. In another embodiment, table, or matrix, 164 in the memory element correlates various offers 122 with associated volume control levels. In a further embodiment, the volume control level for a particular offer is selected by a combination of user defined rules and artificial intelligence, for example, as disclosed by commonly-owned U.S. patent application labeled “METHOD AND SYSTEM FOR GENERATING, SELECTING, AND RUNNING EXECUTABLES IN A BUSINESS SYSTEM UTILIZING A COMBINATION OF USER DEFINED RULES AND ARTIFICIAL INTELLIGENCE,” inventors Otto et al., filed Nov. 9, 2007.

In this fashion, offers that require greater attention or that the retailer wants to emphasize may be associated with or otherwise have a generally louder volume setting, while other messages, for example, information messages reading back an order's content, might have a generally lower volume.

System 100 can be implemented in any kiosk application such as those at airports, grocery stores, big box retailers, gas stations, for example, gas pumps that have an associated speaker, or with any other self-checkout or other kiosk or retail TV applications. For example, a bar room TV could be designed to increase or decrease the volume based upon the ambient noise in the bar or even shut off the volume if the jukebox is playing.

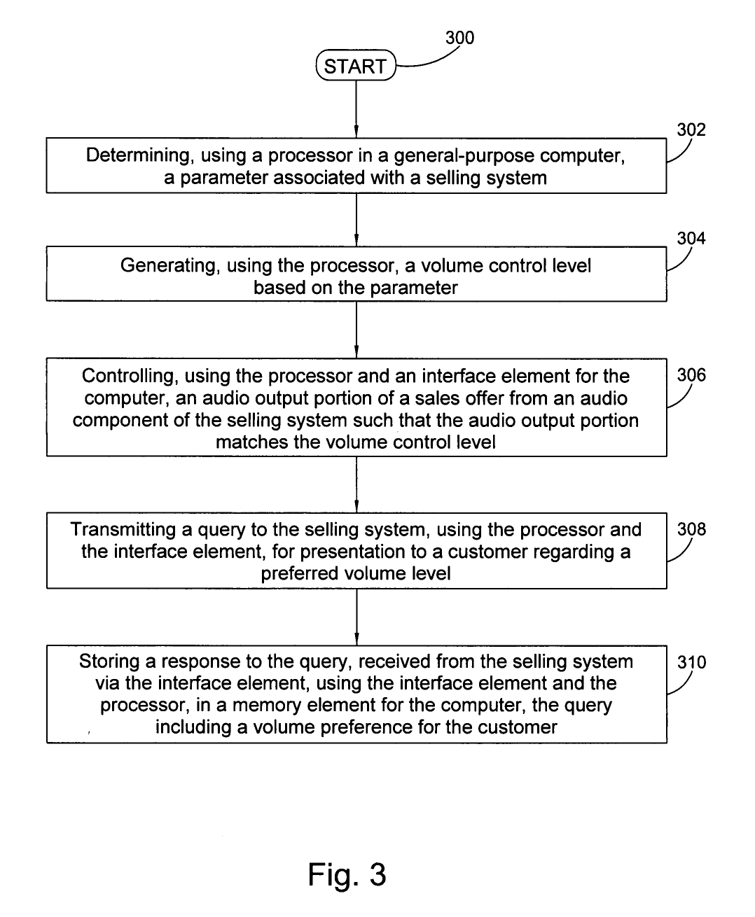

FIG. 3 is a flow chart illustrating a present invention method of adjusting volume for a marketing system. Although the method in FIG. 3 is depicted as a sequence of numbered steps for clarity, no order should be inferred from the numbering unless explicitly stated. The method starts at Step 300. Step 302 determines, using a processor in a general-purpose computer, a parameter associated with the marketing, or selling, system. Step 304 generates, using the processor, a volume control level based on the parameter. Step 306 controls, using the processor and an interface element for the computer, an audio output portion of a sales offer from an audio component of the selling system such that the audio output portion matches the volume control level. The general-purpose computer is arranged to perform the steps of determining, generating, and controlling.

In a preferred embodiment, the parameter is an ambient noise level proximate the selling system and determining a parameter includes measuring the ambient noise level proximate the selling system. In a first embodiment, the parameter is a temporal parameter and determining a parameter includes determining a current temporal parameter. In a further embodiment, the temporal parameter is a time of day or a day of week. In a second embodiment, the parameter is a volume of transactions during a specified time period in a retail location in which the sales system is located and determining a parameter includes determining the volume of transactions. In a further embodiment, the specified time period is a current time or a previous period of time.

In a third embodiment, the selling system is associated with a point of sale (POS) device, the parameter is the identity of personnel operating the POS device, and determining a parameter includes identifying the personnel. In a fourth embodiment, the parameter is the identity of a customer engaged with the selling system and determining a parameter includes identifying the customer. In a further embodiment, identifying the customer includes retrieving a volume preference for the customer from a memory element for the computer and generating a volume control level includes using the volume preference as the volume control level.

In a fifth embodiment, step 308 transmitting a query to the selling system, using the processor and the interface element, for presentation to the customer regarding a preferred volume level and step 310 stores a response to the query, received from the selling system via the interface element, using the interface element and the processor, in a memory element for the computer. The query includes a volume preference for the customer, the general-purpose computer is specially programmed to perform the steps of transmitting and storing, and determining a volume level includes using the volume preference as the volume level. In a sixth embodiment, the parameter is the profitability associated with operation of the selling system and determining a parameter includes determining profitability associated with a volume control level. In a further embodiment, determining profitability includes using a set of rules and an artificial intelligence program to determine profitability.

Thus, it is seen that the objects of the invention are efficiently obtained, although changes and modifications to the invention should be readily apparent to those having ordinary skill in the art, without departing from the spirit or scope of the invention as claimed. Although the invention is described by reference to a specific preferred embodiment, it is clear that variations can be made without departing from the scope or spirit of the invention as claimed.

What is claimed is:

1. A method for adjusting volume for a selling system, comprising the steps of:
determining, using a processor in a general-purpose computer, a parameter associated with the selling system;
generating, using the processor, a volume control level based on the parameter; and,
controlling, using the processor and an interface element for the computer, an audio output portion of a sales offer from an audio component of the selling system such that the audio output portion matches the volume control level, wherein the general-purpose computer is arranged to perform the steps of determining, generating, and controlling.

2. The method of claim 1 wherein the parameter is an ambient noise level proximate the selling system and wherein determining a parameter includes measuring the ambient noise level proximate the selling system.

3. The method of claim 1 wherein the parameter is a temporal parameter and wherein determining a parameter includes determining a current temporal parameter.

4. The method of claim 4 wherein the temporal parameter is a time of day or a day of week.

5. The method of claim 1 wherein the parameter is a volume of transactions during a specified time period in a retail location in which the sales system is located and wherein determining a parameter includes determining the volume of transactions.

6. The method of claim 5 wherein the specified time period is a current time or a previous period of time.

7. The method of claim 1 wherein the selling system is associated with a point of sale (POS) device, the parameter is the identity of personnel operating the POS device, and determining a parameter includes identifying the personnel.

8. The method of claim 1 wherein the parameter is an identity of a customer engaged with the selling system and wherein determining a parameter includes identifying the customer.

9. The method of claim 8 wherein identifying the customer includes retrieving a volume preference for the customer from a memory element for the computer and wherein generating a volume control level includes using the volume preference as the volume control level.

10. The method of claim 8 including the steps of:
transmitting a query to the selling system, using the processor and the interface element, for presentation to the customer regarding a preferred volume level; and,
storing a response to the query, received from the selling system via the interface element, using the interface element and the processor, in a memory element for the computer, wherein the query includes a volume preference for the customer and wherein the general-purpose computer is specially programmed to perform the steps of transmitting and storing and wherein determining a volume level includes using the volume preference as the volume level.

11. The method of claim 1 wherein the parameter is a profitability associated with operation of the selling system and wherein determining a parameter includes determining profitability associated with a volume control level.

12. The method of claim 11 wherein determining profitability includes using a set of rules and an artificial intelligence program to determine profitability.

13. A system for adjusting volume for a selling system, comprising:
a parameter determination element, in a processor of a specially programmed general-purpose computer, arranged to determine a parameter associated with the selling system;
a generating element in the processor arranged to generate a volume control level based on the parameter; and,
a control element in the processor arranged to control, via an interface element for the computer, an audio output portion of a sales offer from an audio component of the selling system such that the audio output portion matches the volume control level.

14. The system of claim 13 wherein the parameter is an ambient noise level proximate the selling system and the system includes a noise sensing element arranged to generate and transmit a signal proportional to an ambient noise level proximate the selling system and wherein the parameter determination element is arranged to accept the signal via the interface element.

15. The system of claim 13 wherein the parameter is a temporal parameter and wherein the parameter determination element is arranged to determine a current temporal parameter.

16. The system of claim 15 wherein the temporal parameter is a time of day or a day of week.

17. The system of claim 13 wherein the parameter is a volume of transactions during a specified time period in a retail location in which the sales system is located and wherein the parameter determination element is arranged to determine the volume of transactions.

18. The system of claim 17 wherein the specified time period is a current time or a previous period of time.

19. The system of claim 13 wherein the selling system is associated with a point of sale (POS) device, the parameter is the identity of personnel operating the POS device, and the parameter determination element is arranged to identify the personnel.

20. The system of claim 13 wherein the parameter is the identity of a customer engaged with the selling system and wherein the parameter determination element is arranged to identify the customer.

21. The system of claim 20 wherein the parameter determination element is arranged to use a volume preference for the customer, retrieved from a memory element for the computer, as the volume control level.

22. The system of claim 20 including:
a query element in the processor arranged to transmit, using the interface element, a query to the selling system for presentation to the customer regarding a preferred volume level;
a response element in the processor arranged to store in a memory element for the computer, a response to the query received via the interface element wherein the query includes a volume preference for the customer and wherein the parameter determination element is arranged to use the response as the volume level.

23. The system of claim 13 wherein the parameter is a profitability associated with operation of the selling system and wherein the parameter determination element is arranged to determining profitability associated with a volume control level.

24. The system of claim 23 wherein the parameter determination element is arranged to determine profitability using a set of rules and an artificial intelligence program.
